(19) United States
(12) Patent Application Publication
(10) Pub. No.: US 2011/0262867 A1
(43) Pub. Date: Oct. 27, 2011

(54) METHOD OF CREATING AN EVALUATION MAP, SYSTEM, METHOD OF MANUFACTURING A SEMICONDUCTOR DEVICE AND COMPUTER PROGRAM PRODUCT

(76) Inventors: Taiga UNO, Yokohama-shi (JP); Yukiyasu Arisawa, Yokohama-shi (JP)

(21) Appl. No.: 13/052,840

(22) Filed: Mar. 21, 2011

(30) Foreign Application Priority Data
Apr. 22, 2010 (JP) 2010-098957

(51) Int. Cl. G03F 7/20; G06F 17/50

(52) U.S. Cl. 430/319; 716/52

(57) ABSTRACT

According to one embodiment, evaluation map creating method is disclosed. The method determines number (N) of times on changing division starting position of layout for segmenting the layout into areas M to create the map by segmenting the layout into areas m and obtaining evaluation value v corresponding to area m (P1). The layout is divided by areas M larger than area m by changing the position, centers of k pieces of areas mk among areas m coincide centers of k pieces of areas M among areas M (P2). Pattern densities D of the layout in areas M is obtained (P3). Evaluation values Vk on areas Mk are calculated by convolving pattern density D for each of areas M with distribution function F (P4). The P2-P4 are repeated N times and obtained N pieces of evaluation values Vk are synthesized (P5).

### CROSS-REFERENCE TO RELATED APPLICATIONS

This application is based upon and claims the benefit of priority from Japanese Patent Application No. 2010-098957, filed Apr. 22, 2010; the entire contents of which are incorporated herein by reference.

### FIELD

Embodiments described herein relate generally to a method of creating an evaluation map to be used for a semiconductor process, a system, a method of manufacturing a semiconductor device, and a computer program product.

### BACKGROUND

Advance in the scale reduction of a semiconductor integrated circuit has been made year after year. With the foregoing advance, the wavelength of a light source of an exposure apparatus becomes short. After a half pitch (HP) 30-nm generation, EUV (Extreme Ultra Violet) having a shorter wavelength is considered to be mainly used in place of ArF.

When a wavelength is set as λ and an optical numeral aperture is set as NA, the resolution of an exposure transfer pattern is expressed by a mathematical formula factor x λ/NA. This mathematical formula means that a fine pattern is formable when the wavelength λ is small. The EUV has a wavelength shorter than ArF. For this reason, when the EUV is used, the resolution is improved, and it is possible to form a finer pattern.

An exposure technique (EUV exposure) of achieving a short wavelength using EUV has points different from a conventional exposure technique. A lens and a mask are given as one of largely different points.

First, a lens will be simply described below. In a conventional exposure technique, a refractive lens is used as a lens optical system. However, a EUV light does not transmit a refractive lens from the relationship between a light absorption and a refractive index. For this reason, in EUV exposure, a reflection optical system (mirror) is used in place of the refractive lens.

A mask a lens will be simply described below. In a conventional exposure technique, a transmission-type mask is used. On the other hand, in EUV exposure, a reflection-type mask is used. The reflection-type mask has a reflection area for partially reflecting EUV (exposure light), and an absorption area (non-reflection area) for absorbing EUV (exposure light).

By the way, in EUV exposure, a mirror used for a reflection optical system has a surface with a concavo-concave portion (roughness). This is because the mirror surface is polished in a process of producing a mirror, however, the mirror surface can not be fully polished flatly.

If the mirror surface has a roughness, in an exposure process, EUV light (exposure light) irradiated onto the mirror surface is irregularly reflected. The irregularly reflected exposure light (scattered light) is exposed on an area on a wafer resist, which should not be exposed. The scattered light exposed onto a wafer is called as a flare.

If a flare is exposed onto an area of resist which should not be exposed, the contrast of light intensity distribution on the resist is reduced. The reduction of the contrast is a factor of causing the following problem. Namely, a latent image pattern formed on the resist is blurred, and therefore, a desired resist pattern is not formed properly. Moreover, the flare is different in its amount depending on the different between coarse and dense of a surrounding layout pattern; in other words, the difference between surrounding brightness. The phenomenon is a factor of causing a problem that the uniformity of wafer in-plane dimension is not obtained in patterns even though having the same design dimension. For this reason, the flare is given as one of a big factor of reducing the accuracy of the critical dimension in EUV Lithography.

In order to solve the flare problem, a pattern correction must be made taking a flare into consideration. In order to make a pattern correction, there is a need to estimate a flare value. With the scale reduction of a semiconductor device, a high accurate flare prediction is required.

A method of estimating flare value is known in which a circuit pattern layout area is segmented by predetermined intervals (referred to as “grid”), then a pattern density of each segmented area is calculated, and flare value is estimated by convolving the calculated pattern density with a point spread function (PSF). The point spread function (PSF) is, for example, a Gaussian function or a fractal function. A function approximating the function may be used in place of the point spread function.

On this occasion, the following technique may be given. According to the technique, the following flare values are calculated. A flare value (first flare value) obtained by segmentation using a coarse grid having a predetermined intervals equal to a fixed value or more. A flare (second flare value) is obtained by segmentation using a fine grid having a predetermined interval smaller than the fixed value. A flare value of the whole area of the circuit pattern layout is obtained by summing the first flare value and the second flare values.

The technique further proposes a means for finding a area having a poor uniformity of flare value, and a means for finding the area having the poor uniformity of flare value and correcting the uniformity of flare value by adding a dummy pattern to the founded area.

Other technique proposes a calculating method of flare amount and a flare correction. In the calculating method of the flare amount, a circuit pattern layout area is segmented, and then, brightness (pattern density) on the each of the segmented areas is calculated Then, the convolution integral of the brightness and a point spread function is carried out for each of the segmented areas. In the method of the flare correction method, an edge is biased in accordance with the calculated flare amount as the correction.

As for a prediction of the flare value in the technique, a circuit pattern layout area is divided into a plurality of areas (hereinafter, referred to as meshes), and a pattern density is calculated for each of the meshes. A density map is created by using the calculated pattern density of each mesh.

The flare map is a distribution of flare values obtained by the calculation performed on each mesh. A flare correction is performed by using the flare map, for example, a bias is applied to a pattern in the mesh in accordance with a flare value corresponding to the mesh.

One flare value only is given to one mesh of the flare map. For this reason, if there is a large difference of flare amount distribution in one mesh, the flare correction accuracy is reduced. In order to improve the accuracy, there is a need to make small a mesh size so that the difference of the flare amount distribution of the mesh becomes small. However, if the mesh size is made small, the number of meshes is increased, and the calculation amount increases.

Here, usually a flare value on a predetermined mesh position (x, y) is obtained from the following equation.

$$Flare ( x , y ) = {\sum }_{X} {\sum }_{Y} ( Density ( X , Y ) \times P S {F}_{F} ( \sqrt{( {( X - x )}^{2} + {( Y - y )}^{2} )} ) \times Mesh\_Area )$$

where,

Flare (x, y): flare value on mesh position (x, y)

Density (x, y): pattern density on mesh position (x, y)

PSF_{F} (dist): a function for calculating a PSF value on a distance between meshes (e.g., see FIG. 15)

Mesh_Area: mesh area

From the equation, it can be seen tat the calculation considerably depends on the number of meshes.

For example, if the mesh width size is made half, the number of meshes becomes four times, the calculation amount per one mesh becomes four times, and the calculation amount for all meshes becomes 16 times.

Therefore, the method of reducing the mesh size affects largely on calculation time, and the method is not a practical solution.

### BRIEF DESCRIPTION OF THE DRAWINGS

FIG. 1 is a histogram showing a dispersion of error of a flare value of a mesh (flare prediction accuracy);

FIG. 2 is a view showing a square mesh having one side of 1 μm and four corner points of lower left, upper left, lower right and upper right in the square mesh;

FIG. 3 is a graph showing the relationship between a mesh size and an error of flare value on a center position of a mesh (flare prediction accuracy);

FIG. 4 is a flowchart to explain a method of creating a flare map according to an embodiment;

FIG. 5 is a view showing the arrangement of four 0.5 μm meshes for one 1 μm mesh;

FIGS. 6A, 6B, 6C and 6D are views showing an example that four-time shifts of 1 μm mesh allow the centers of 1 μm mesh coincide with the centers of four 0.5 μm meshes;

FIG. 7 is a view schematically showing a calculation area frame (0.5 μm frame) comprising 16 pieces of 0.5 μm meshes;

FIG. 8 is a view schematically showing a calculation area frame (1 μm frame) comprising nine piece of 1 μm meshes;

FIG. 9 is a view to explain step S2 of method of creating a flare map according to an embodiment;

FIG. 10 is a view to explain step S3 of a method of creating a flare map according to an embodiment;

FIG. 11 is a view to explain step S5 of a method of creating a flare map according to an embodiment;

FIG. 12 is a histogram showing a dispersion of an error of a flare value of a mesh (flare prediction accuracy) according to an embodiment;

FIG. 13 is a view to explain an effect of an embodiment (reduction of calculation);

FIG. 14 is a graph showing one example of a point spread function (PSF); and

FIG. 15 is a view to explain a computer program product according to an embodiment.

### DETAILED DESCRIPTION

An embodiment will be hereinafter described with reference to the accompanying drawings.

In general, according to one embodiment, a method of creating an evaluation map for evaluating a mask to be used for a semiconductor process is disclosed. The evaluation map including a plurality (j pieces) of areas m and a plurality (j pieces) of evaluation values V. The plurality (j pieces) of areas m is associated with the plurality (j pieces) of evaluation values V. The plurality (j pieces) of areas m segment a layout of the mask into j pieces. The method includes determining a number (N) of times on changing a division starting position of the layout for dividing the layout by a plurality of areas M, the plurality of the areas M is larger than the plurality areas m in size (P1). Further, the layout is divided by the plurality areas M by changing the division starting position, centers of k pieces (k<j) of areas m (areas mk) among the plurality (j pieces) of the areas m respectively coinciding with centers of k pieces of areas M (areas Mk) among the plurality of the areas M (P2). The method further includes obtaining a pattern density D of the layout in the area M for each of the areas M (P3). The method further includes calculating an evaluation value Vk on each of k pieces of areas Mk by convolving the pattern density D for each of area M with a distribution function F, wherein the distribution function F expresses a dispersion of evaluation value relating to a semiconductor process (P4). Wherein the P2, P3 and P4 are repeated the number of times (N) determined in the P1, and the method further includes synthesizing N pieces of the evaluation values Vk obtained by the N times of the P4 (P5).

The following is a description of the study result earnestly made by inventors.

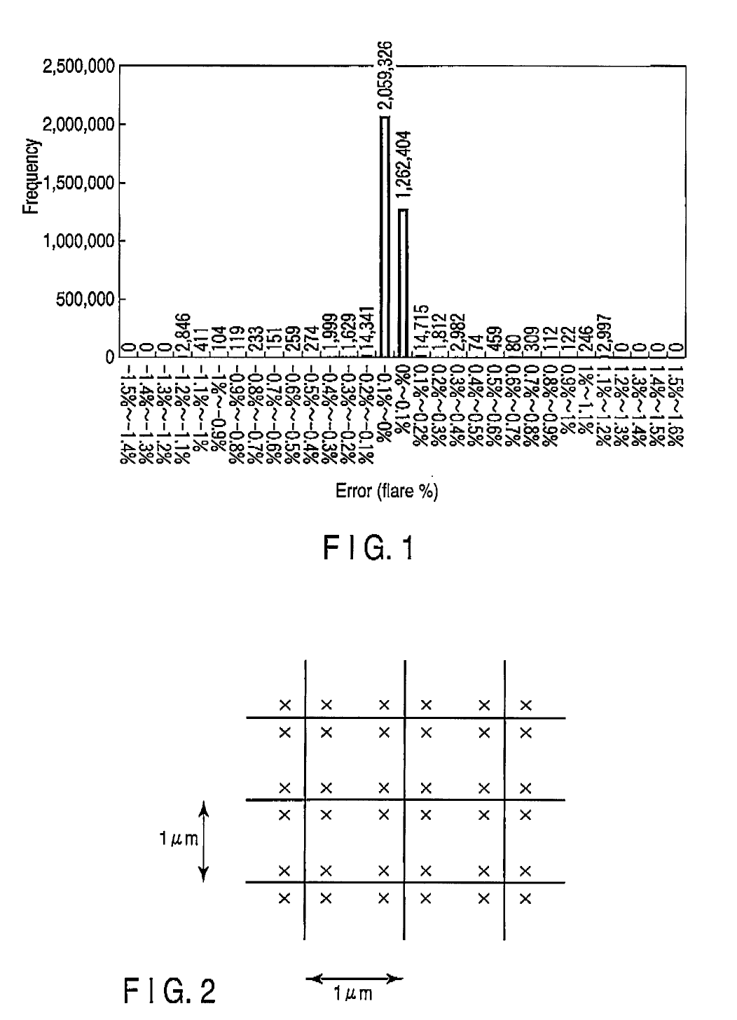

FIG. 1 is a histogram showing a dispersion of a flare value of a mesh. Here, the shape of the mesh is a square, and the size of the mesh (mesh size) is a length of on a side of the square. The present embodiment uses a mesh having square shape, but the present embodiment is also applicable to a mesh having shape other than square.

In FIG. 1, the horizontal axis shows data interval dividing error (%) of flare value by an interval of 0.1, and the vertical axis shows frequency of error occur for each of the intervals.

Here, the flare value shows a ratio of a flare, which is irradiated to a wafer (resist), to the case where a total reflection light of a mask whose entire surface is set as a reflection area is set to 100%. Usually, the flare value is expressed using a percentage (%). The error of the flare value is defined as “prediction flare value−strict flare value”.

The prediction flare value is a flare value (calculated by a known method), which is calculated by carrying out convolution integration of a density map and a point spread function (PSF).

The point spread function (PSF) is a distribution data showing a spread of a flare when a very small hole pattern (point pattern) is exposed. In place of the point spread function (PSF), a function approximating to the foregoing data, for example, a Gaussian function, or a fractal function may be used.

The strict flare value is a flare value, which is calculated by carrying out a convolution integration of a layout pattern (not the density map) and a point spread function (PSF). The strict flare value corresponds to a prediction flare value when the mesh size is unlimitedly closed to 0.

Therefore, the error of the flare value defined above reflects an accuracy (flare prediction accuracy) of flare value, which is estimated using a known method.

When the flare is calculated by using the density map, the flare value calculated in one mesh area is one. This means that a prediction accuracy is reduced if there exists a large dispersion in the flare intensity in a mesh in-plane. An in-plane accuracy of each mesh is calculated, and then, the histogram is shown in FIG. 1.

The following portions (evaluation points) are set in order to verify a prediction accuracy of a flare value in a mesh in-plane (error). As can be seen from FIG. 2, four corner points, (shown by x in FIG. 2), that is, lower left, upper left, lower right and upper left points are set in a square mesh having one side of 1 μm (mesh size). In this way, the difference between strict calculations is taken with respect to all meshes.

As can be seen from FIG. 1, when a mesh size is 1 μm, the spread range (error range) of this histogram is about 2.36%, that is, exceeds 2% in the four corner points. Considering lithography transfer accuracy on wafer, the error range must be about 0.6% or less on calculation. This value is calculated on the assumption that a prediction dimensional error by a flare prediction is set as ±1 nm, and a CD sensitivity to flare is set as 3 nm/% (necessary accuracy≈±1/3≈±0.333, and therefore, an error range is about 0.6%). In the present embodiment, the error range is set to 0.5% slightly stricter than the necessary accuracy. Therefore, when the mesh size is 1 μm, the flare prediction accuracy is insufficient.

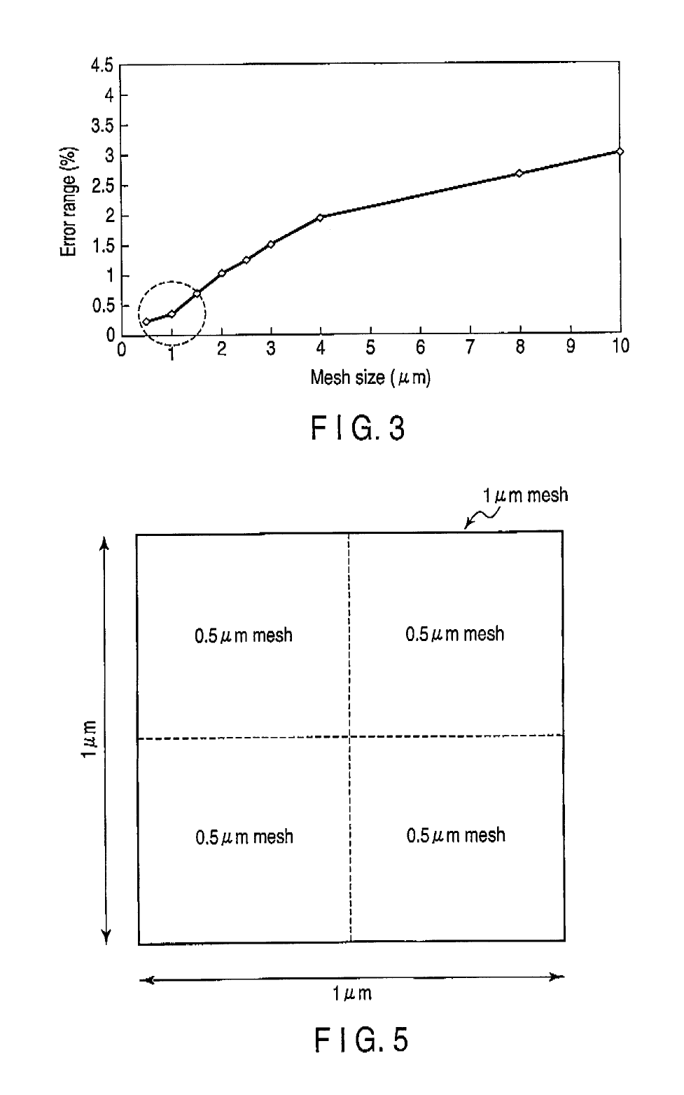

On the other hand, the relationship between a mesh size and an error (flare prediction accuracy) of a flare value on the center position of a mesh is investigated, and the result shown in FIG. 3 is obtained. In FIG. 3, the horizontal axis takes a mesh size, and the vertical axis takes an error range on the center position of a mesh.

As can be seen from FIG. 3, the flare prediction accuracy on the center position of a mesh is as follows. Namely, the smaller the mesh size becomes, the smaller the error range becomes, therefore, it can be seen that this improves the prediction accuracy. Further, it can be seen that the error range is reduced to 0.5% or less if the mesh size is less than 1 μm.

That is, according to the earnest study made by inventors, it become clear that the center position of mesh allow a high accuracy prediction of flare value even if the mesh size is not so made small.

The following is a description of a method of creating a flare map according to the present embodiment using the foregoing study result.

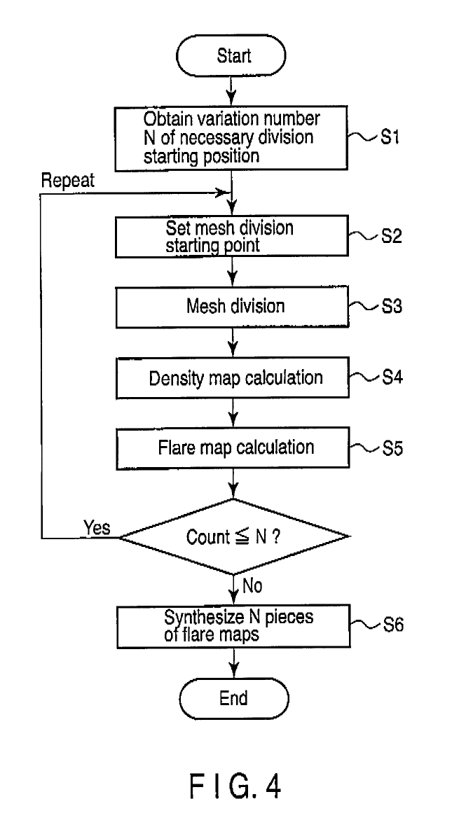

FIG. 4 is a flowchart to explain a method of creating a flare map according to the present embodiment. According to the present embodiment, a method of creating a flare map having a mesh size 0.5 μm based on a density map having a mesh size 1 μm is given as an example.

As shown in FIG. 3, when a mesh size is 1 μm, an error range is less than an allowable value (0.5%) on the mesh center position, therefore, the evaluation point on the mesh center position is able to estimate a flare value with high accuracy.

However, as depicted in FIG. 1, an error range exceeds an allowable value (0.5%) at a position out of the mesh center position, therefore, the evaluation point on the position out of the mesh center position is hard to estimate a flare value with high accuracy.

So, in the present embodiment, the following shift is employed using the result that it is possible to estimate a flare value with high accuracy on the mesh center position. The division starting position of the mesh is shifted so that the mesh center position is to be the position of a requiring accuracy (division start position shift).

The division start position shift is further explained.

As shown in FIG. 5, four (2×2) meshes (0.5 μm mesh) having a mesh size 0.5 μm can be entered in a mesh (1 μm mesh) having a mesh size 1 μm.

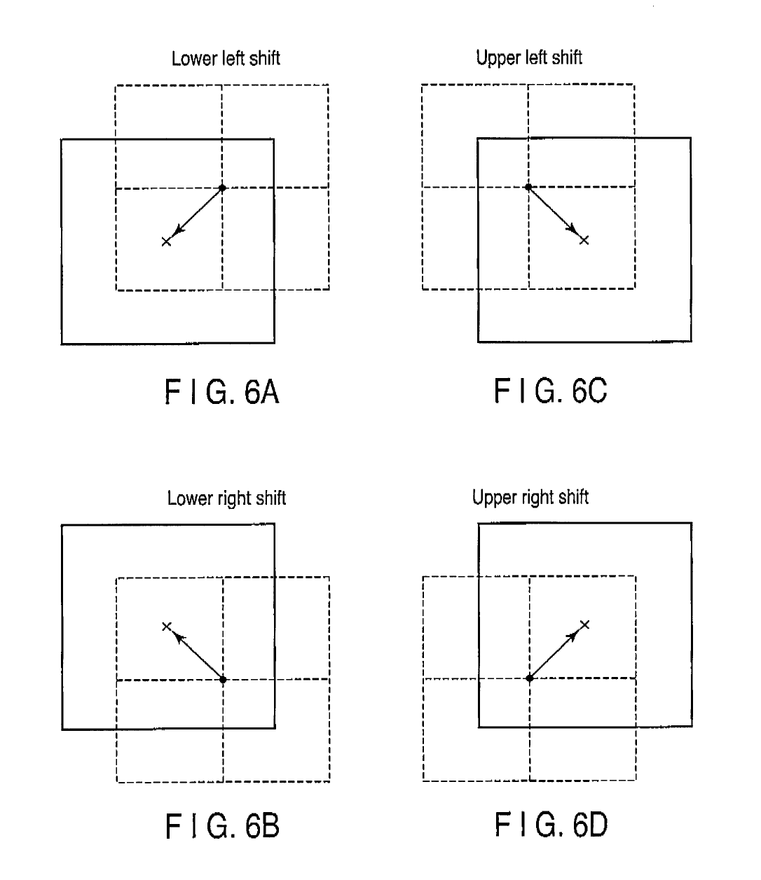

When the 1 μm mesh of FIG. 5 is shifted to four directions of lower left, upper left, lower right and upper right directions as shown in FIGS. 6A to 6D, all of the center positions (x mark) of four 0.5 μm meshes (broken line) can be coincide with the center position of the 1 μm mesh (solid line). In FIGS. 6A to 6D, a black circle denotes the center position of the 1 μm mesh before shifting, and a x mark denotes the center position of the 1 μm mesh after shifting.

Therefore, 4 (=2×2) is obtained as the variation number N of a necessary mesh division starting position (step S1 (P1)).

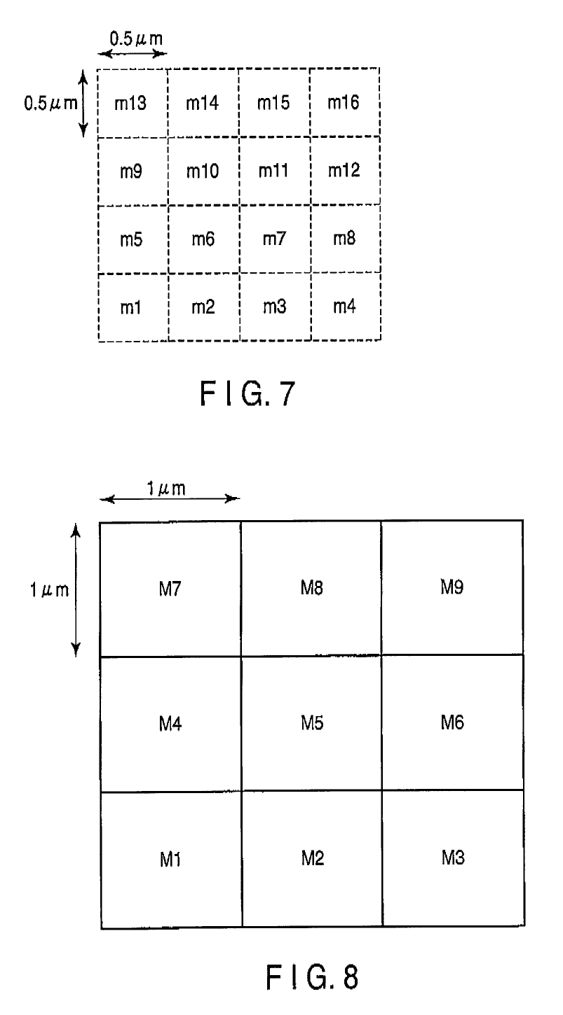

FIG. 7 is a view schematically showing a frame (0.5 μm frame), which comprises 16 (j) 0.5 μm meshes m1 to m16 (area m).

FIG. 8 is a view schematically showing a frame (1 μm frame), which comprises nine (j) 1 μm meshes M1 to M9 (area M).

Here, relating to flare values obtained by calculation later, flare values corresponding to m1 to m16 positions are defined as f1 to f16, and flare values corresponding to M1 to M9 positions are defined as F1 to F9.

Hereinafter, a mesh-shaped frame having a predetermined size will be referred to simply as frame.

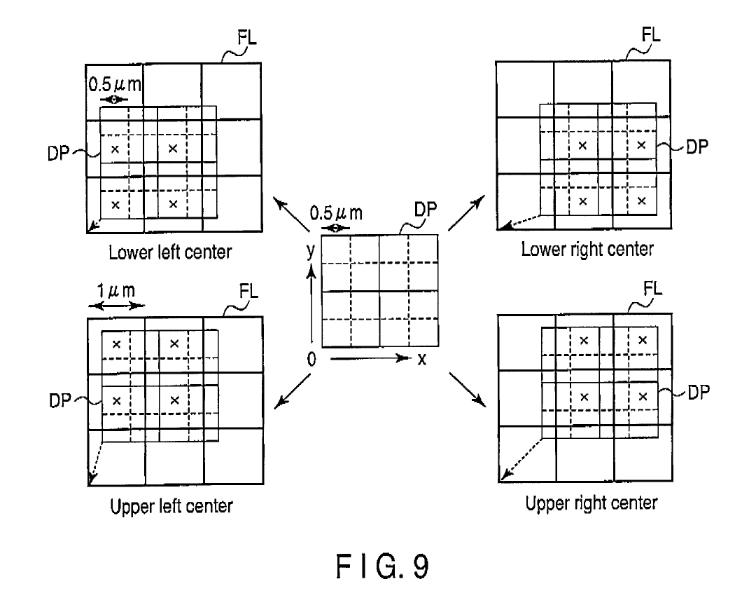

FIG. 9 is a view to explain a method of creating a new density map (N density map), which does not exist in the conventional case, using a 0.5 μm frame and a 1 μm frame. In the present embodiment, the number of N is 4.

In FIG. 9, DP denotes a 0.5 μm mesh frame shown in FIG. 7, and FL denotes a 1 μm frame shown in FIG. 8.

In FIG. 9, a reference number for specifying each mesh is not given, but each mesh is specified according to reference numbers (m1, m2 . . . m16, M1, M2 . . . M9) shown in FIG. 7 and FIG. 8. Moreover, the lower left corner of the mesh m1 of the 0.5 μm frame is set as the origin, and the horizontal direction is set as the x direction while the vertical direction is set as the y direction.

A 1 μm frame is shifted with respect to a 0.5 μm frame so that the center (lower left center) of the lower left mesh of the 1 μm frame coincides with the center (lower left center) of the lower left mesh of the 0.5 μm frame (step S2).

That is, the 1 μm frame is shifted with respect to the 0.5 μm frame so that the center of the mesh M1 coincides with the center of the mesh m1 (area mk). Specifically, the 1 μm frame is shifted by −0.25 μm in the x direction, and shifted by −0.25 μm in the y direction.

In this case (lower left center coincidence), the centers of mesh M2 and mesh m3 (area mk), the centers of mesh M4 and mesh m9 (area mk), and the centers of mesh M5 and mesh m11 (area mk) also coincide respectively.

Next, as illustrated in FIG. 10, a layout pattern is divided by using a 1 μm frame which is shifted so that the lower left center coincides (S3 (P)), and a density calculation is performed for each of areas to create a 1 μm density map (S4 (P)).

For example, the pattern density is calculated as 0.0 (0.0%) when the all patterns in the mesh correspond to an absorption area of a reflection mask, and the pattern density is calculated as 1.0 (100.0%) when the all patterns in the mesh correspond to a reflection area of the reflection mask.

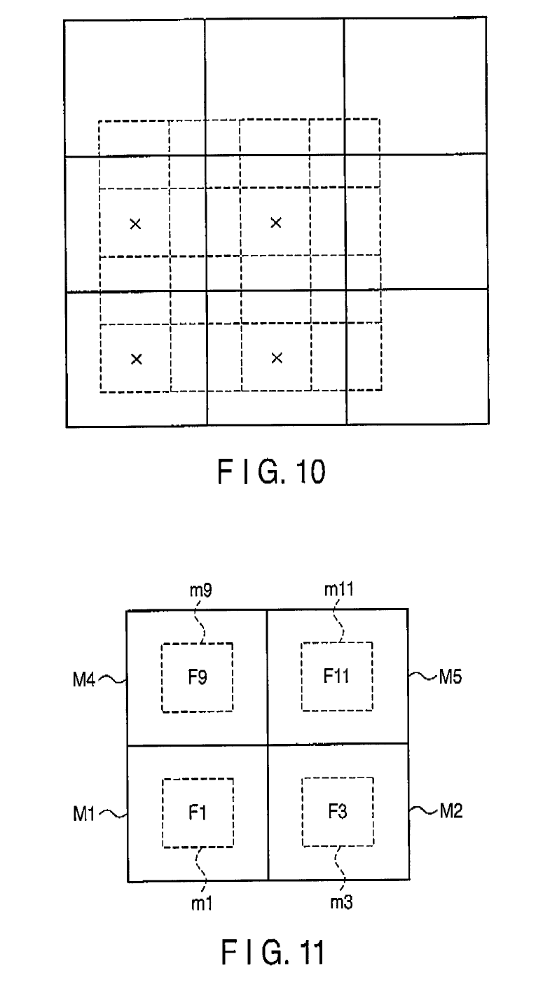

Next, as shown in FIG. 11, flare values F1, F2, F4 and F5 (the center coincides with f1, f3, f9 and f11) in meshes M1, M2, M4 and M5 (the center coincides with mesh m1, m3, m9 and m11) of the density map are calculated by convolving the density map of 1 μm mesh size with a point spread function and a flare map (first flare map) is created (step S5 (P4)).

Even though the calculation is performed by 1 μm mesh size, the calculation is performed by utilizing the flare value at the center position of the mesh resulting in small error range (high prediction accuracy), so the increase of calculation amount may be prevented while the flare value may be estimated with high accuracy by using the calculated flare values F1, F2, F4 and F5 as the flare values (f1, f3, f9 and f11) of m1, m3, m9 and m11 of 0.5 μm frame in FIG. 7.

In the case of lower left center coincidence, meshes M1, M2, M4 and M5 each have the coincided center as described above, so the information required for creating the flare map (first flare map) are flare values F1, F2, F4 and F5.

However, when a convolution library function in a general calculation library is used, the flare values F1 to F9 of all meshes M1 to M9 may be calculated. The reason comes from the fact that a calculation library is considerably optimized so that a specialist perform a high-speed calculation, therefore, there is a possibility that a high-speed calculation is performed compared with the case of calculating flare values F1, F2, F4 and F5 only by using originally created program.

The above explanation is directed in a case of calculating partial flare values having meshes of 0.5 μm size by shifting the 1 μm frame such that the center of the 0.5 μm density map coincides the center of the 1 μm frame at the lower left.

Likewise, the flare map (second, third and fourth flare maps) are created as follows. The 1 μm frame is shifted by −0.25 μm in the x direction and by −0.75 μm in the y direction so that the centers coincide at the upper left center to create a 1 μm density map. Then, convolution integration of the created 1 μm density map and the point spread function is calculated to create the flare map (second flare map). Further, the 1 μm frame is shifted by −0.75 μm in the x direction and by −0.25 μm in the y direction so that the centers coincide at the lower right center to create a 1 μm density map. Then, convolution integration of the created 1 μm density map and the point spread function is calculated to create a flare map (third flare map). Further, a 1 μm frame is shifted by −7.25 μm in the x direction and by −7.25 μm in the y direction so that the centers coincide at the upper right center to create a 1 μm density map. Then, convolution integration of the created 1 μm density map and the point spread function is calculated to create a flare map (fourth flare map).

The creating the second flare map serves to prevent an increase of calculation amount, and corresponds to calculate flare values of meshes m5, m7, m13 and m15 in the 0.5 μm frame of FIG. 7.

The creating the third flare map serves to prevent an increase of calculation amount, and corresponds to calculate flare values of meshes m2, m4, m10 and m12 in the 0.5 μm frame of FIG. 7.

The creating the fourth flare map serves to prevent an increase of calculation amount, and corresponds to calculate flare values of meshes m6, m8, m14 and m16 in the 0.5 μm frame of FIG. 7.

Here, the frame size (mesh size) is the same in all of the four time (N times) shifting procedures, but the frame size may be changed in all of the four time (N times) shifting procedures or in some of the four time (N times) shifting procedures as long as the flare value at the center position with a desired accuracy is achieved. In this case, when the areas mk are overlapped, any one of areas mk may be employed. Even if any areas mk is employed, the desired accuracy is achieved obtained, so no problem arises.

Next, the first flare map, the second flare map, the third flare map, and the fourth flare maps are synthesized (step S6 (P5)).

A flare map having a high precision corresponding to the 0.5 μm frame of FIG. 7 is obtained by synthesizing the first to fourth flare maps.

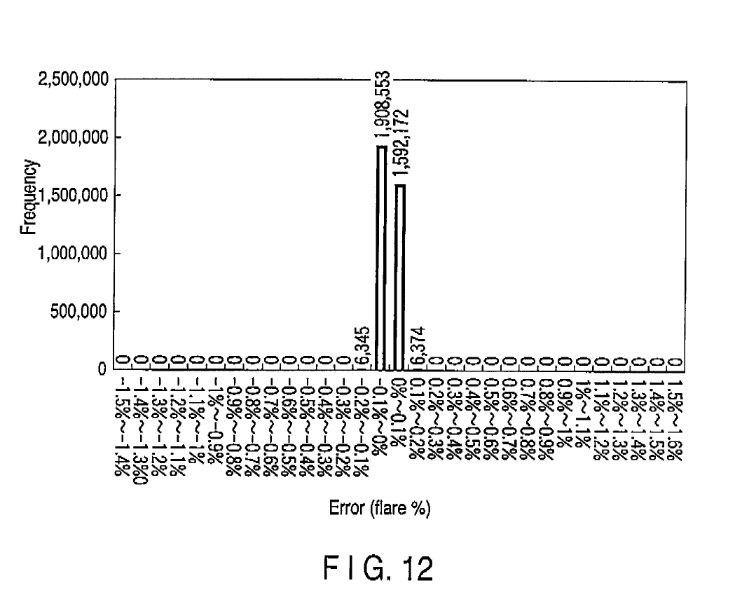

FIG. 12 is a histogram showing a dispersion of the flare value of the mesh of the present embodiment. The error range of the conventional mesh shown in FIG. 1 is 2.36% in positions except the mesh center position, but the error range of the mesh of the present embodiment is 0.35% from FIG. 12, which shows that the flare prediction accuracy is improved in the present embodiment.

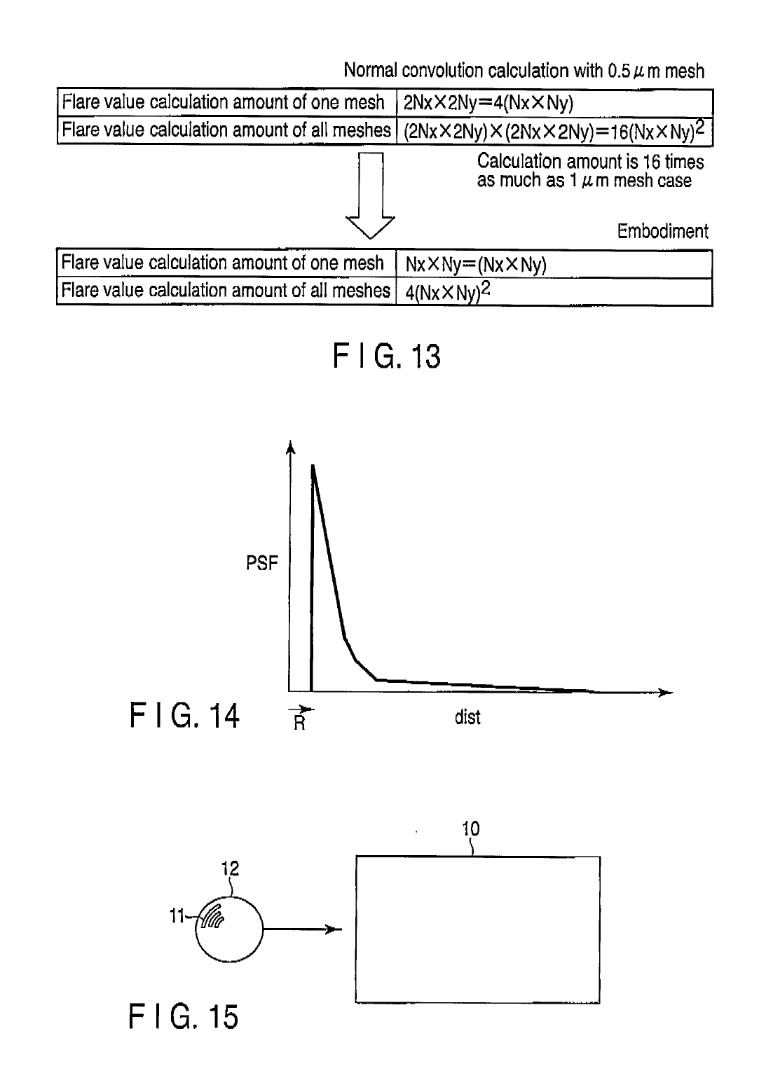

In addition, relating to calculation amount, as can be seen from FIG. 13, the method of the present embodiment affords a reduced calculation amount which is ¼ calculation amount obtained by conventional method which calculates the flare value using the mesh size of 0.5 μm only.

The present embodiment includes a step which has not been taken in the conventional method, the step is directed to obtain the flare map having the desired mesh size by performing the plurality of flare calculations with shifting the frame of the mesh having mesh size larger than the desired mesh size.

However, the most time taking step for creating the flare map lies in a calculation step since the calculation time of the convolution calculation needed for obtaining the flare values is dominant in the calculation step.

Therefore, according to the present embodiment, the total time spent for creating the flare map may be considerably reduced compared with the conventional case.

As described above, according to the present embodiment, even though the mesh division is performed by the mesh larger than mesh size required for securing accuracy in the flare map creation, it is possible to suppress the increasing of flare map creation time, and to create the flare map having improved flare map accuracy, by utilizing the flare value at the center position of the mesh resulting in high estimation accuracy.

Moreover, it is possible to perform a pattern correction with high accuracy by adding bias to a pattern in a mesh, in which the bias is a flare value corresponding to the mesh, and the flare value is determined by using the flare map of the present embodiment.

The present invention is not limited to the above embodiment.

The above embodiment relates to a method of creating an evaluation map (method of flare calculation) for evaluating the flare of reflection-type mask to be used for a lithography process, however, the present invention is also applicable to a method of creating an evaluating map for evaluating a mask to be used for other semiconductor processes. For example, it is applicable to a method of creating an evaluating map for evaluating a mask to be used for processing process to be affected by coarse/dense of pattern density or girth (distance around pattern) in a large area such as area subjected to etching process or CMP process (method of calculating variation amount of dimension such as dimension subjected to coarse/dense pattern density or girth).

Moreover, the calculation for flare value may be implemented by using a system. That is, the system of the present embodiment comprises a calculation unit to calculate the flare value of the present embodiment by using a pixel-based bitmap expression of polygons converted in a pixel-based bitmap expression and having a predetermined configuration, in which the pixel-based bitmap includes a plurality of pixel data, each of the plurality of the pixel data expresses a pixel having a predetermined pixel size, and the calculation unit comprises programmable gate arrays to concurrently process the plurality of the pixel data.

Moreover, a method of manufacturing a semiconductor device of the present embodiment comprises a step of evaluating a mask (reflection-type) to be used for a lithography process (EUV exposure) by using the evaluation map created by the method of creating the evaluation map of the present embodiment, and a step of performing the semiconductor process (EUV exposure) by using the mask (reflection-type) which is determined allowable in a step of evaluating the mask.

Moreover, the above evaluation method of the present embodiment can also be carried out in the form of a computer program product (e.g., CD-ROM, DVD) 12 that contains a program 11 for executing a system including a computer 10.

For example, the computer program product 12 according to the evaluation method of the present embodiment causes the computer 10 to execute instructions corresponding to steps S1 through S6 of FIG. 4. The steps S1 to S6 may be executed by the computer as a means or functions.

The program 11 is executed using hardware resources, such as a CPU and memory in the computer (external memory may be concurrently used for the memory, depending on the case). The CPU reads necessary data from the memory, and executes the step (instruction) or the steps (instructions) for the read data. The result of the respective step (instruction) is temporarily stored by necessary in the memory, and is read out when it is required in the other step (instruction).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the sprit of the inventions. The accompanying claims and their equivalents are intended to cover such forms or modifications as would fall within the scope and spirit of the inventions.

What is claimed is:

1. A method of creating an evaluation map for evaluating a mask to be used for a semiconductor process, the evaluation map including a plurality (j pieces) of areas m and a plurality (j pieces) of evaluation values V, the plurality (j pieces) of areas m being associated with the plurality (j pieces) of evaluation values V, and the plurality (j pieces) of areas m segmenting a layout of the mask into j pieces;
the method comprising:
determining a number (N) of times on changing a division starting position of the layout for segmenting the layout into a plurality of areas M, the plurality of the areas M being larger than the plurality areas m in size (P1);
segmenting the layout into the plurality areas M by changing the division starting position, centers of k pieces (k<j) of areas m (areas mk) among the plurality (j pieces) of the areas m respectively coinciding with centers of k pieces of areas M (areas Mk) among the plurality of the areas M (P2);
obtaining a pattern density D of the layout in the area M for each of the areas M (P3); and
calculating an evaluation value Vk on each of k pieces of areas Mk by convolving the pattern density D for each of areas M with a distribution function F, wherein the distribution function F expresses a dispersion of evaluation value relating to a semiconductor process (P4),
wherein the P2, P3 and P4 are repeated the number of times (N) determined in the P1, and further comprising synthesizing N pieces of the evaluation values Vk obtained by the N times of the P4 (P5).

2. The method according to claim 1, wherein the evaluation of the mask to be used for the semiconductor process is a flare evaluation of a reflection-type mask to be used for a lithography process, the evaluation value v is a flare value, and the evaluation map is a flare map.

3. The method according to claim 2, wherein the flare value is obtained by using a convolution library function.

4. The method according to claim 1, wherein the distribution function F is a point spread function.

5. The method according to claim 4, wherein the point spread function is a Gaussian function or a fractal function.

6. The method according to claim 1, wherein the plurality of the areas M comprises areas M1-Mn having sizes S1-Sn respectively, the sizes S1-Sn are different each other, and the size of area M used in the N times of the P2 are different each other.

7. A system comprising:
a calculation unit configured to calculate a flare value by using a pixel-based bitmap expression of a plurality of polygons converted in a pixel-based bitmap expression and having a predetermined configuration;
wherein the flare value is a flare value of claim 2, the pixel-based bitmap includes a plurality of pixel data, each of the plurality of the pixel data expresses a pixel having a predetermined pixel size, and the calculation unit comprises a plurality of programmable gate arrays configured to concurrently process the plurality of the pixel data.

8. A method of manufacturing a semiconductor device comprises:
evaluating a mask to be used for a semiconductor process by using an evaluation map created by a method of creating an evaluation map of claim 1; and
performing the semiconductor process by using a mask which is determined allowable in the evaluating the mask.

9. The method according to claim 5, wherein the evaluation of the mask to be used for the semiconductor process is a flare evaluation of a reflection-type mask to be used for a lithography process, the evaluation value v is a flare value, and the evaluation map is a flare map.

10. The method according to claim 8, wherein the distribution function F is a point spread function.

11. A computer program product configured to store program instructions for execution on a computer system enabling the computer system to perform: a method of creating an evaluation map for evaluating a mask to be used for a semiconductor process, the evaluation map including a plurality (j pieces) of areas m and a plurality (j pieces) of evaluation values V, the plurality (j pieces) of areas m being associated with the plurality (j pieces) of evaluation values V, and the plurality (j pieces) of areas m segmenting a layout of the mask into j pieces;
the program instructions comprising:
an instruction to determine a number (N) of times on changing a division starting position of the layout for segmenting the layout into a plurality of areas M, the plurality of the areas M being larger than the plurality areas m in size (I1);
an instruction to segment the layout into the plurality areas M by changing the division starting position, centers of k pieces (k<j) of areas m (areas mk) among the plurality (j pieces) of the areas m respectively coinciding with centers of k pieces of areas M (areas Mk) among the plurality of the areas M (I2);
an instruction to obtain a pattern density D of the layout in the area M for each of the areas M (I3); and
an instruction to calculate an evaluation value Vk on each of k pieces of areas Mk by convolving the pattern density D for each of areas M with a distribution function F, wherein the distribution function F expresses a dispersion of evaluation value relating to a semiconductor process (I4),
wherein the P2, P3 and P4 are repeated the number of times (N) determined in the P1, and further comprising an instruction to synthesize N pieces of the evaluation values Vk obtained by the N times of the P4 (I5).
